(19) United States
(12) Patent Application Publication
(10) Pub. No.: US 2007/0205354 A1
(43) Pub. Date: Sep. 6, 2007

(54) Image sensor light shield

(75) Inventor: Jiutao Li, Boise, ID (US)

Correspondence Address: DICKSTEIN SHAPIRO LLP, 1825 EYE STREET, NW, WASHINGTON, DC, 20006, US

(73) Assignee: MICRON TECHNOLOGY, INC.

(21) Appl. No.: 11/367,581

(22) Filed: Mar. 6, 2006

(51) Int. Cl. H01L 27/00; H01L 31/00

(52) U.S. Cl. 250/208.1; 250/214.1

(57) ABSTRACT

A structure and method of reducing optical cross talk in an image sensor by using a light shield having light shield portions comprising a plurality of separated blocks of opaque material above each pixel cell's photosensor. The light shield portions have an aperture allowing light to pass through to the photosensor associated with the pixel cell. The blocks are separated from each other by a distance shorter than the wavelength of visible light; as such, the space created between the blocks mitigates the passing of wavelengths of incident light therethrough to undesired areas.

### FIELD OF THE INVENTION

The present invention generally relates to light shields for image sensors.

### BACKGROUND OF THE INVENTION

Solid-state image sensors, also known as imagers, absorb incident radiation of a particular wavelength (such as optical photons, x-rays, or the like) and generate an electrical signal corresponding to the absorbed radiation. There are different types of semiconductor-based image sensors, including charge coupled devices (CCD's), photodiode arrays, charge injection devices, hybrid focal plane arrays, and complementary metal oxide semiconductor (CMOS) image sensors.

CMOS image sensors typically consist of a focal plane array of pixel cells. Each one of the pixel cells includes a photosensor, generally a photogate, photoconductor or a photodiode, overlying a substrate for accumulating photo-generated charge in the underlying portion of the substrate. A readout circuit is connected to each pixel cell and includes at least an output transistor formed in the substrate and a charge storage region, typically a floating diffusion region, formed on the substrate adjacent the photosensor and connected to the gate of the output transistor. The image sensor may include at least one electronic device such as a transistor for transferring charge from the underlying portion of the substrate to the floating diffusion region and one device, also typically a transistor, for resetting the region to a predetermined charge level prior to charge transference.

In a CMOS image sensor, the active elements of a pixel cell perform the necessary functions of: (1) photon to charge conversion; (2) accumulation of image charge; (3) transfer of charge to the floating diffusion region accompanied by charge amplification; (4) resetting the floating diffusion region to a known state; (5) selection of a pixel cell for readout; and (6) output and amplification of a signal representing pixel cell charge. Photo charge may be amplified when it moves from the initial charge accumulation region to the floating diffusion region. The charge at the floating diffusion region is typically converted to a pixel cell output voltage by a source follower output transistor.

Exemplary CMOS image sensors of the type discussed above are generally known as discussed, for example, in U.S. Pat. Nos. 6,140,630, 6,376,868, 6,310,366, 6,326,652, 6,204,524 and 6,333,205, each assigned to Micron Technology, Inc., which are incorporated herein by reference in their entirety.

Photosensors in each pixel cell produce a signal corresponding to the intensity of light impinging on the photosensors. When an image is focused on the array of pixel cells, the combined signals may be used, for example, to form a digital representation of the image which may be stored, displayed, printed, and/or transmitted. Accordingly, it is important that all of the light directed to the photosensor impinges on that photosensor rather than becoming reflected or refracted. If light does not impinge on the correct photosensor, optical crosstalk between pixel cells may occur.

Optical crosstalk may exist between neighboring photosensors in a pixel cell array of a solid-state image sensor. In an idealized photosensor, a photodiode for example, light enters only through the surface of the photodiode that directly receives light. In reality, however, light intended for neighboring photosensors also enters the photodiode, in the form of stray light, through the sides of the photosensor structure for example. Reflection and refraction within an array of pixel cells can give rise to stray light, which is also referred to as optical crosstalk.

Optical crosstalk can bring about undesirable results in images that are produced. The undesirable results can become more pronounced as the density of pixel cells in image sensor arrays increases, and as pixel cell size correspondingly decreases. The shrinking pixel cell sizes make it increasingly difficult to focus incoming light on the photosensor of each pixel cell.

Optical crosstalk can manifest as a blurring or reduction in contrast in images produced by a solid-state image sensor. In essence, optical crosstalk in an image sensor array degrades the spatial resolution, reduces overall sensitivity, causes color mixing, and leads to image noise after color correction. As noted above, image degradation can become more pronounced as pixel cell and sensor sizes are reduced.

One method to reduce optical crosstalk in an image sensor is to use a light shield. Typical image sensors include a light shield providing apertures exposing at least a portion of the photosensors to incoming light while shielding the remainder of the pixel cells from the light. Ideally, light shields can block received light signals of adjacent pixel cells and prevent photocurrent from being generated in undesirable locations in the pixel cells; thus, the image sensor achieves higher resolution images with less blooming, blurring, and other detrimental effects. Light shields can also protect the circuitry associated with the pixel cells, for example, from radiation damage and from using stray light that could be undesirably converted in the circuitry to part of this pixel cell's output signal.

In the prior art, various back end polymer based light shield materials have been used; however, none of them attain a light blocking effectiveness greater than metal. Ideally, for perfect light blocking, one continuous layer of metal would be used as the light shield in the image sensor. The light shield typically is formed above the circuitry and the photosensors associated with the pixel cells. The light shield also has apertures allowing light to pass through to the photosensors. Examples of light shields formed in image sensors are provided in U.S. Pat. Nos. 6,611,013 and 6,812,539, each assigned to Micron Technology, Inc., which are incorporated herein by reference in their entirety.

There are, however, some undesired properties related to metal light blocking shields in image sensors. Light shields have typically been formed in the metal interconnect layering (e.g., metal 1, metal 2, or, if utilized, metal 3 layers) of the image sensor, but this type of light shield arrangement limits the use of the metal layer to the light shield rather than for its normal conductive interconnect purpose (for example, conductive connections for the image sensor). In general, using one continuous block of metal as a light shield for an electrical device may cause conflicts with how components of that sensor conducts power or signaling. Also, having the light shield in upper metallization layers spaced from the photosensors can increase light piping and light shadowing in the pixel cells, which can cause errors in sensor functioning.

Another problem with metal light shields relates to the amount of stress imposed onto the image sensor. For example, achieving good light blocking could require more than a 500 Å thick tungsten layer. Applying a large tungsten layer could introduce significant stress to the device, which could introduce higher dark current, leakage current, and in the worst case, could cause film peel off that causes severe process problems. Accordingly, a light shield for an image sensor that does not suffer from the above shortcomings is desired.

### BRIEF SUMMARY OF THE INVENTION

The present invention provides a structure and method of improving image sensor performance, for example reducing optical crosstalk, by using a light shield having light shield portions comprising a plurality of opaque material blocks above each pixel cell's photosensor. The light shield portions are arranged to form an aperture allowing light to pass through to the photosensor associated with the pixel cell. The light shield portions are also arranged to form spacing between the blocks which prevents all or at least a portion of wavelengths of incident light from passing therethrough at locations where it is desired to block light.

For light shields where a metal is used for the material blocks, the exemplary light shield of the invention reduces the total net stress on the substrate's surface because it is composed of small blocks (per light shield portion), rather than one continuous block of metal. A material block may be any shape or size; therefore, the light shield is not limited in where it can be placed on the image sensor. The light shield could be placed at locations close to the substrate or at one of the conductive interconnect layers (e.g., metal 1 layer or higher). The light shield, if formed of metal, could be placed without electrical contact to other metal layouts. However, a block forming part of the light shield could be connected to other metal layouts if electrical connection is desired.

### BRIEF DESCRIPTION OF THE DRAWINGS

These and other advantages and features of the present invention will be more apparent from the following detailed description and drawings which illustrate various embodiments of the invention in which:

FIG. 1 shows an exemplary embodiment of a pixel cell and a light shield constructed in accordance with the invention;

FIG. 2 is a partial cross-sectional view of the pixel cell and the light shield of FIG. 1 through line 2-2′;

FIG. 3 shows a CMOS image sensor in accordance with the invention; and

FIG. 4 illustrates a processor system incorporating at least one CMOS image sensor, constructed in accordance with the invention.

### DETAILED DESCRIPTION OF THE INVENTION

In the following detailed description, reference is made to the accompanying drawings, which are a part of the specification, and in which is shown by way of illustration various embodiments whereby the invention may be practiced. These embodiments are described in sufficient detail to enable those skilled in the art to make and use the invention. It is to be understood that other embodiments may be utilized, and that structural, logical, and electrical changes, as well as changes in the materials used, may be made without departing from the spirit and scope of the present invention. Additionally, certain processing steps are described and a particular order of processing steps is disclosed; however, the sequence of steps is not limited to that set forth herein and may be changed as is known in the art, with the exception of steps or acts necessarily occurring in a certain order.

The terms “wafer” and “substrate” are to be understood as interchangeable and as including silicon, silicon-on-insulator (SOI) or silicon-on-sapphire (SOS), doped and undoped semiconductors, epitaxial layers of silicon supported by a base semiconductor foundation, and other semiconductor structures. Furthermore, when reference is made to a “wafer” or “substrate” in the following description, previous process steps may have been utilized to form regions, junctions or material layers in or on the base semiconductor structure or foundation. In addition, the semiconductor need not be silicon-based, but could be based on silicon-germanium, germanium, gallium arsenide, or other known semiconductor materials.

The terms “pixel” or “pixel cell” refer to a photo-element unit cell containing a photosensor and transistors for converting electromagnetic radiation to an electrical signal. Although the invention is described herein with reference to the architecture and fabrication of one pixel cell, it should be understood that this is representative of a plurality of pixel cells in an array of an image sensor. In addition, although the invention is described below with reference to a CMOS image sensor, the invention has applicability to any solid state image sensor having pixel cells. The following detailed description is, therefore, not to be taken in a limiting sense, and the scope of the present invention is defined only by the appended claims.

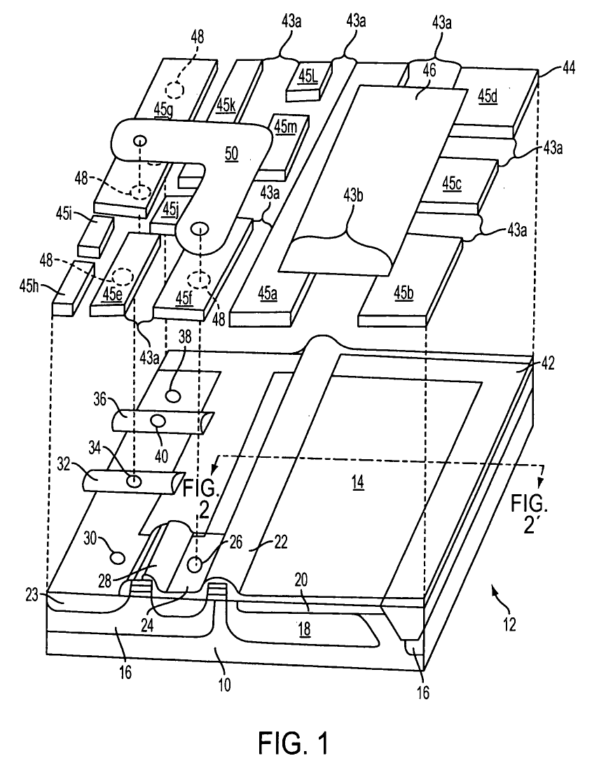

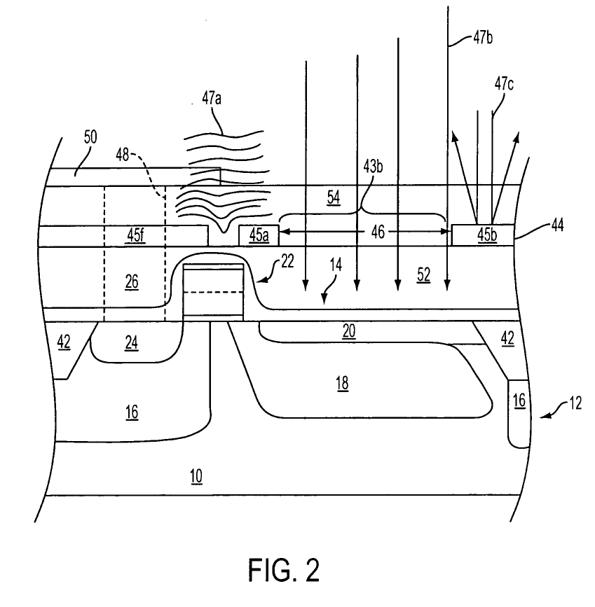

Now referring to the figures, FIGS. 1 and 2 show an exemplary embodiment of the invention, shown in a CMOS pixel cell 12 formed partially in and over a doped p-type region 16 in a substrate 10, and includes a photosensor 14, a transfer gate 22, a reset gate 28, a source follower gate 32, and a row select gate 36. The photosensor 14 includes an n-type conductivity region 18 and an uppermost thin p-type conductivity layer 20 over the n-type region 18. The transfer gate 22 forms part of a transfer transistor for electrically gating the charges accumulated by photosensor 14 to a floating diffusion region 24. A first conductor 26 at the floating diffusion region 24 is in electrical communication with the source follower gate 32 of a source follower transistor through a second conductor 34, connected by a conductive path 50 in a conductive interconnect layer which may be provided, for example, in the metal 1 (or first metal) layer. Sharing the floating diffusion region 24 with the transfer transistor is a reset transistor having reset gate 28. The reset transistor is connected to a voltage source through a source/drain region having a conductor 30 providing a resetting voltage to the floating diffusion region 24 when the reset transistor is activated.

It should be understood that while FIGS. 1 and 2 show the circuitry for a single pixel cell 12, in practical use there will be an M×N array of pixel cells 12 formed in substrate 10 and arranged in rows and columns with the pixel cells 12 of the array being accessed using row and column select circuitry, as is known in the art. The pixel cell 12 shown can be laterally isolated from other pixel cells of the array by shallow trench isolation regions 42. Although the isolation region 42 is shown only along two sides of the pixel cell 12 for simplicity, in practice trench isolation regions may extend around the entire perimeter of the pixel cell 12. It should be noted that the pixel cell 12 is merely exemplary of one embodiment in which the invention may be used. The construction and operation of pixel cell 12, or the use of a CMOS pixel cell in a CMOS array, is thus not limiting of the invention.

A light shield 44 can be formed above the substrate 10 for precluding at least a portion incident light from passing through to undesired areas of the array of pixel cells 12. One exemplary embodiment of the invention, as shown in FIGS. 1 and 2, provides each pixel cell 12 with a light shield 44 formed above the photosensor 14 and associated circuitry. The light shield 44 has a plurality of opaque light shield portions arranged and spaced to provide an aperture 46 allowing light to pass through to the photosensor 14 of each pixel cell 12. The light shield 44 also prevents all or at least a substantial portion of incident light from passing through to other areas of each pixel cell 12 and to neighboring pixel cells.

Light shield 44 comprises light shield portions formed as a plurality of opaque material blocks 45a, 45b, 45c, 45d, 45e, 45f, 45g, 45h, 45i, 45j, 45k, 45l, and 45m per pixel cell 12. The light shield 44 material can comprise WSix, W, TiN, Ti, Co, Cr, poly/WSiₓ, Al, Ti/Al, TiSi₂/Al, and Ti/Al/TiN, Mo, Ta or other materials with desired light-blocking, electrical, and physical characteristics. For example, refractal metal materials such as tungsten have a higher temperature tolerance; therefore, a tungsten light shield could be applied at locations very close to the substrate 10 surface. Aluminum light shields could be used in the conductive interconnect layer 50 (i.e., metal 1 layer), which is relatively close to the substrate's 10 surface.

In an exemplary embodiment, the light shield 44 may comprise a plurality of metal material blocks 45a, 45b, 45c, 45d, 45e, 45f, 45g, 45h, 45i, 45j, 45k, 45l, and 45m per pixel cell 12. Unlike one continuous block of metal as a light shield, using smaller blocks of metal to form a light shield prevents high stress on the silicon surface. Breaking the metal into smaller pieces distributes the amount of metal stress on the substrate; therefore, the total net stress would be less than comprising the light shield of one large continuous block of metal. It should be appreciated that blocks comprising of metal materials is only one exemplary embodiment of the invention. A material block may comprise any opaque material which prevents at least a portion of wavelengths of incident light from passing through.

The light shield 44 can be very thin. For example, compared to typical metal interconnect layers, which can be about 1,000 Å to about 10,000 Å thick, the light shield 44 need only be thick enough to prevent at least a portion of incident light 47c from passing through (i.e., about 100 Å to about 3,000 thick). The specific thickness within this range can be determined by the light absorption/reflection properties of the light shield 44 material. It is preferred that less than 1% of light impacting the light shield 44 be able to penetrate to the underlying pixel cell 12.

The light shield comprising a plurality of material blocks 45a, 45b, 45c, 45d, 45e, 45f, 45g, 45h, 45i, 45j, 45k, 45l, and 45m can be arranged such that the blocks are separated from each other by a first distance 43a to provide a space of sufficient size to prevent at least a portion of wavelengths of incident light 47a from passing through, and a second distance 43b to provide the aperture 46 of sufficient size to allow light 47b to pass through. In the illustrated embodiment, material blocks 45b, 45c and 45d of light shield 44 are arranged to be separated from material block 45a by the second distance 43b to define the aperture 46 over the photosensor 14, thereby allowing light 47b to pass through to the photosensor 14. The first distance 43a between material blocks 45b, 45c and 45d precludes at least a portion of wavelengths of incident light 47a from passing through to undesired areas of the pixel cell 12. The material blocks are opaque and thick enough allowing less than 1% of incident light 47c impacting each material block to penetrate through to the underlying pixel cell 12 (e.g., material block 45a). Material blocks 45b, 45c and 45d can also be arranged to prevent at least a portion of incident light from passing through to neighboring pixel cells. A material block, if conductive, can optionally be electrically grounded by a grounding circuit, by which it can provide electrical shielding to the underlying pixel cell 12 circuitry. Openings 48 are provided in material blocks 45e, 45f and 45g to allow the various circuitry contacts 26, 30, 34, 40, 38 to be in electrical communication between overlying conductive interconnect layer 50 and underlying pixel circuitry, e.g., 22, 28, 32, 36.

TABLE 1
Electromagnetic Simulation of Light Intensity on the Surface or Inside
the Silicon (Si) Substrate.

| | AI Block | First | Flux on Si | | 0.5 um in Si | | 1.5 um in Si | |
|---|---|---|---|---|---|---|---|---|
| | width | Distance | (aubitrary | Light | (aubitrary | Light | (aubitrary | Light |
| | (um) | (um) | unit) | Attenuation | unit) | Attenuation | unit) | Attenuation |
| 1 | 0 | infinite | 1.16E−10 | | 1.20E−10 | | 3.46E−11 | |
| 2 | 0.15 | 0.15 | 3.97E−14 | 3.43E−04 | 2.70E−14 | 2.24E−04 | 1.13E−14 | 3.27E−04 |
| 3 | 0.3 | 0.13 | 7.41E−16 | 6.40E−06 | 5.39E−16 | 4.48E−06 | 6.69E−17 | 1.93E−06 |

Table 1 compares (1) a photosensor without a light shield comprising opaque material blocks over the photosensor, (2) an aluminum material block with 0.15 um width and 0.15 um first distance 43a, and (3) an aluminum material block with 0.3 um width and 0.4 um first distance. As shown, using a light shield comprising metal material blocks has a 4 to 6 order of magnitude of light intensity reduction, which is ideal for image sensors.

FIG. 2 shows a cross section of a portion of the FIG. 1 pixel cell 12 taken along the line 2-2′. As is shown, a light transparent first dielectric layer 52 can be provided over the pixel cell 12 having an upper surface above the level of the transistor gates, e.g., transistor gate 22, of the pixel cell 12. Light shield 44 is formed over the first dielectric layer 52. A second dielectric layer 54 having similar light transmitting and insulating properties as the first dielectric layer 52 can be formed over the light shield 44 (and within the aperture 46). A conductive interconnect layer 50, i.e., metal 1 layer may be formed over second dielectric layer 54, which may be connected by contacts (e.g., conductor 26) to the underlying circuitry provided in openings 48 through the various layers 54, 52 and 44. Additional dielectric, conductive interconnect, or passivation, color filter and micro lens layers can be formed over the conductive interconnect layer 50, but are not shown as they are well known in the art.

As illustrated in FIGS. 1 and 2, adjacent material blocks, e.g., 45b and 45c, 45c and 45d, 45a and 45f, 45a and 45m, 45a and 45l, 45f and 45e, 45f and 45j, 45f and 45m, 45e and 45h, 45e and 45j, 45e and 45i, 45h and 45i, 45i and 45g, 45g and 45j, 45g and 45k, 45j and 45k, 45k and 45m, 45k and 45l, 45l and 45m are separated from each other by the first distance 43a. The first distance 43a defines a space being sufficient in size to prevent at least a portion of wavelengths of incident light 47a from pass through to the pixel cells. The first distance 43a is determined by the process used to make the image sensor. The first distance 43a should be any length shorter than the wavelength of visible light 47a. In another exemplary embodiment, a pixel cell array comprising a plurality of pixel cells 12, each associated with a color filter (e.g., red, green and blue) and thus, associated with a wavelength of light passed by the filter, can have the first distance 43a determined based upon the associated wavelength of light, so that at least a portion of the wavelength of light can be blocked.

As is known in the art, light is electromagnetic radiation with a wavelength that is visible to the human eye, (i.e., visible light). Wave transmission can be described by electromagnetic theory. For example, when a plane wave meets a Faraday cup electromagnetic shield it diffracts if the opening of the cup is smaller than the wavelength. The transportation properties of an electromagnetic wave are relative to the wavelength and the opening of the cup. The electromagnetic radiation intensity will decrease as

$$I \sim {( \frac{a}{λ} )}^{4} ,$$

where a is the cup open diameter and A is the wavelength.

When the opening of the cup is smaller than the wavelength, the percentage of wave penetration is significantly reduced.

For effective light shielding, the preferred first distance 43ashould be less than or equal to about 0.4 um, which is about one quarter of the wavelength of visible light. As illustrated in FIG. 2, when visible light 47a meets the opening (i.e., a space defined by the first distance 43a) between adjacent material blocks (e.g., 45e and 45f where light blocking is desired) the electromagnetic waves diffract spreading the waves instead of propagating them in a straight line. As a result, at least a portion of visible light 47a is unable to pass through the opening between adjacent material blocks 45e and 45f to undesired areas.

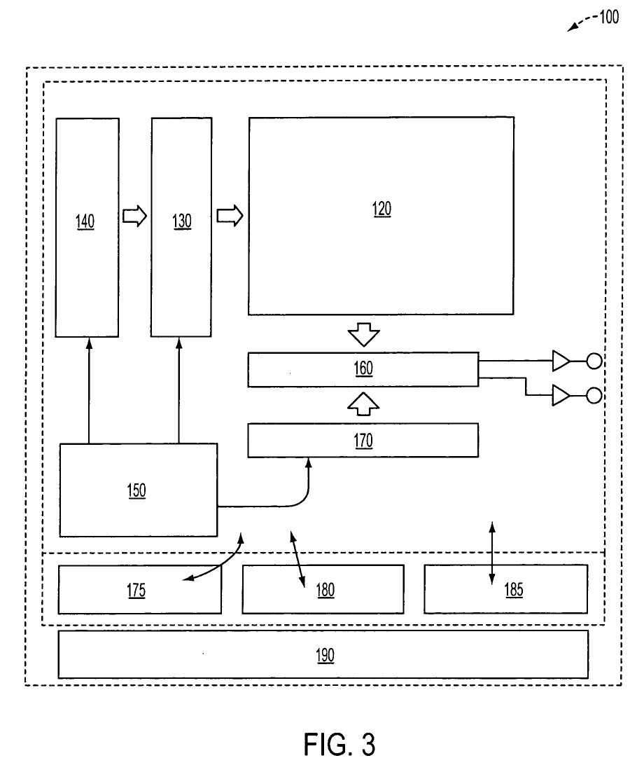

FIG. 3 illustrates a block diagram for a CMOS image sensor 100 having a pixel cell array 120 incorporating pixel cells 12 and light shield 44 constructed in the manner discussed above in relation to FIGS. 1 and 2. Pixel cell array 120 comprises a plurality of pixel cells 12 arranged in a predetermined number of columns and rows. The pixel cells 12 of each row in array 120 can all be turned on at the same time by a row select line and the pixel cells 12 of each column are selectively output onto output lines by column select lines. A plurality of row and column lines is provided for the entire array 120. The row lines are selectively activated by the row driver 130 in response to row address decoder 140 and the column select lines are selectively activated by the column driver 160 in response to column address decoder 170. Thus, a row and column address is provided for each pixel cell 12.

The CMOS image sensor 100 is operated by the control circuit 150 which controls address decoders 140, 170 for selecting the appropriate row and column lines for pixel readout, and row and column driver circuitry 130, 160 which apply driving voltage to the drive transistors of the selected row and column lines. A memory 175, e.g., an SRAM, can be in communication with the array 100 and control circuit 150. A serializer module 180 and SFR (Special Function Register) device 185 can each be in communication with the control circuit 120. Optionally, a localized power source 190 can be incorporated into the image sensor 100.

Typically, the signal flow in the image sensor 100 would begin at the array 120 upon its receiving photo-input and generating a charge. The signal is output to a read-out circuit and then to an analog-to-digital conversion device. Then the signal is transferred to a processor, then the serializer, and then the signal can be output from the image sensor to external hardware.

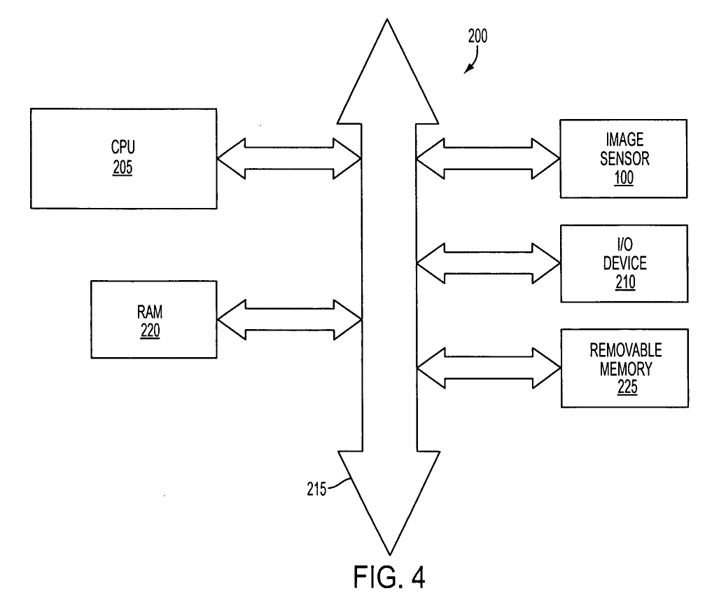

FIG. 4 illustrates a processor system 200 including an image sensor 100 containing pixel cell 12 with light shield 44 constructed in a invention. The processor system 200 is exemplary of a system utilizing an image sensor 100 which includes a pixel array 200 having pixel cell 12 with light shield 44 constructed and operated in accordance with the invention. Without being limiting, such a system could include a camera system, computer system, scanner, machine vision system, vehicle navigation system, cell phone, and others.

The processor system 200, for example a camera system, generally comprises a central processing unit (CPU) 205, such as a microprocessor, that communicates with an input/output (I/O) device 210 over a bus 215. Image sensor 100 also communicates with the CPU 205 over bus 215. The processor system 200 also includes random access memory (RAM) 220, and can include removable memory 225, such as flash memory, which also communicate with CPU 205 over the bus 215. Image sensor 100 may be combined with a processor, such as a CPU, digital signal processor, or microprocessor, with or without memory storage on a single integrated circuit or on a different chip than the processor.

The processes and devices described above illustrate preferred methods and typical devices of many that could be used and produced. The above description and drawings illustrate embodiments, which achieve the objects, features, and advantages of the present invention. However, it is not intended that the present invention be strictly limited to the above-described and illustrated embodiments. Any modification, though presently unforeseeable, of the present invention that comes within the spirit and scope of the following claims should be considered part of the present invention.

What is claimed as new and desired to be protected by Letter Patent of the United State is:

1. An image sensor, comprising:
a photosensor supported on a substrate; and
a light shield comprising a plurality of opaque material blocks associated with and formed above the photosensor, a portion of the plurality of material blocks being arranged to define a light blocking area, the material blocks being separated in the light blocking area by a distance, the distance being less than or equal to the wavelengths of incident light.

2. The image sensor according to claim 1, wherein the distance is less than or equal to about 0.4 um.

3. The image sensor according to claim 1, wherein the distance prevents at least a portion of wavelengths of incident light from passing therethrough.

4. The image sensor according to claim 1, wherein the material blocks comprise a metal material.

5. The image sensor according to claim 1, wherein the material blocks are of a thickness and material so as to allow less than 1% of incident light to pass therethrough.

6. An image sensor, comprising:
a photosensor supported on a substrate; and
a light shield comprising a plurality of metal material blocks associated with and formed above the photosensor, the material blocks being arranged to define a light blocking area, the material blocks being arranged in the light blocking area to be separated by a first distance, the first distance which prevents at least a portion of wavelengths of incident light from passing therethrough, and a light transmission area over the photosensor, the material blocks being arranged in the light transmission area to be separated by a second distance, the second distance allowing light to pass through to the photosensor.

7. The image sensor according to claim 6, wherein the first distance is less than or equal to the wavelengths of incident light.

8. The image sensor according to claim 6, wherein the first distance is less than or equal to about 0.4 um.

9. The image sensor according to claim 6, wherein the material block is of a thickness and material so as to allow less than 1% of incident light to pass therethrough.

10. An image sensor, comprising:
a photosensor supported on a substrate; and
a light shield comprising a plurality of opaque material blocks associated with and formed above the photosensor, the material blocks being arranged to define a light transmission area over the photosensor to allow light to pass through to the photosensor, and a light blocking area, the material blocks being arranged in the light blocking area to be separated by a first distance, the first distance being less than or equal to the wavelengths of incident light.

11. The image sensor according to claim 10, wherein the first distance is less than or equal to about 0.4 um.

12. The image sensor according to claim 10, wherein the first distance prevents at least a portion of wavelengths of incident light from passing therethrough.

13. The image sensor according to claim 10, wherein a portion of the material blocks is separated by a second distance, the second distance providing the light transmission area.

14. The image sensor according to claim 10, wherein the material blocks are isolated from and provide no electrical contact to a conductive interconnect layer of the image sensor.

15. The image sensor according to claim 10, wherein at least one of the plurality of material blocks has electrical contact with a conductive interconnect layer of the image sensor.

16. The image sensor according to claim 10, wherein the material blocks comprise a metal material.

17. The image sensor according to claim 10, wherein the material blocks comprise a material selected from the group consisting of tungsten, tungsten silicide, titanium, titanium nitride, cobalt, chromium, polysilicon-tungsten silicide, aluminum, titanium silicide, molybdenum, tantalum and combinations thereof.

18. The image sensor according to claim 10, wherein the material blocks are about 100 Å to about 3,000 Å thick.

19. The image sensor according to claim 10, wherein the material blocks are of a thickness and material so as to allow less than 1% of incident light to pass therethrough.

20. An image sensor, comprising:
an array contacting a plurality of pixel cells, each pixel cell having a photosensor; and
a plurality of separated opaque material blocks arranged above the pixel cells of the array,
wherein the material blocks are arranged to define an aperture over the photosensor to allow light to pass through to the photosensors of the pixel cells, and to define a light blocking area, the material blocks being arranged in the light blocking area to be separated by a first distance, the first distance being less than or equal to the wavelengths of incident light.

21. The image sensor according to claim 20, wherein the first distance is less than or equal to about 0.4 um.

22. The image sensor according to claim 20, wherein the first distance prevents at least a portion of wavelengths of incident light from passing therethrough.

23. The image sensor according to claim 20, wherein the material blocks comprise a metal material.

24. The image sensor according to claim 20, wherein the material blocks are of a thickness and material so as to allow less than 1% of incident light to pass therethrough.

25. An image sensor system, comprising:
a processor;
an image sensor communicating with the processor, the image sensor comprising:
a pixel cell array having a plurality of pixel cells, each of the pixel cells comprising a photosensor supported on a substrate;
a conductive interconnect layer formed above the photosensor; and
a light shield comprising a plurality of opaque material blocks associated with and formed above the photosensor, the material blocks being arranged to define a light transmission area over the photosensor to allow light to pass through to the photosensor, and to define a light blocking area, the material blocks being arranged in the light blocking area to be separated by a first distance to prevent at least a portion of wavelengths of incident light from passing therethrough.

26. The image sensor system according to claim 25, wherein the first distance is less than or equal to about 0.4 um.

27. The image sensor system according to claim 25, wherein the first distance being less than or equal to the wavelengths of incident light.

28. The image sensor system according to claim 25, wherein the material blocks are arranged in the light transmission area separated by a second distance.

29. The image sensor system according to claim 25, wherein the material blocks comprise a metal material.

30. The image sensor system according to claim 25, wherein the material blocks are of a thickness and material so as to allow less than 1% of incident light to pass therethrough.

31. A method of forming an image sensor comprising the acts of:
forming an array contacting a plurality of pixel cells, each pixel cell having a photosensor; and
forming a plurality of metal material blocks associated with and formed above the photosensor, the material blocks being arranged to define a light blocking area, the material blocks being arranged in the light blocking area to be separated by a first distance to prevent at least a portion of wavelengths of incident light from passing therethrough, and to define a light transmission area over the photosensor, the material blocks being arranged in the light transmission area to be separated by a second distance to allow light to pass through to the photosensor.

32. The method according to claim 31, wherein the first distance is less than or equal to about 0.4 um.

33. The method according to claim 31, wherein the first distance is less than or equal to the wavelengths of incident light.

34. The method according to claim 31, wherein the material blocks are of a thickness and material so as to allow less than 1% of incident light to pass therethrough and can be conductive or insulative material.

35. A method of forming an image sensor comprising the acts of:
forming an array of pixel cells, each pixel cell having a photosensor;
forming a light shield comprising an opaque material above the photosensors; and
patterning the light shield to form a plurality of opaque material blocks per pixel cell associated with and formed above the photosensor, the plurality of material blocks being arranged to define a light blocking area, the material blocks being separated in the light blocking area by a first distance, the first distance being less than or equal to the wavelengths of incident light.

36. The method according to claim 35, further comprising the act of forming a conductive interconnect layer above the photosensor.

37. The method according to claim 35, further comprising of the material blocks being arranged to define a light transmission area, the material blocks being separated in the light transmission area by a second distance to allow light to pass through to the photosensor.

38. The method according to claim 35, wherein the first distance is less than or equal to about 0.4 um.

39. The method according to claim 35, wherein the step of forming the light shield comprises depositing a metal material.

40. The method according to claim 35, wherein the step of forming the light shield comprises depositing a material selected from the group consisting of tungsten, tungsten silicide, titanium, titanium nitride, cobalt, chromium, polysilicon-tungsten silicide, aluminum, titanium silicide, molybdenum, tantalum, and combinations thereof.

41. The method according to claim 35, wherein the step of patterning the light shield forms material blocks about 100 Å to about 3,000 Å thick.

42. The method according to claim 35, wherein the material blocks are of a thickness and material so as to allow less than 1% of incident light to pass therethrough and can be conductive or insulative material.
